(19) United States
(12) Patent Application Publication
(10) Pub. No.: US 2025/0311396 A1
(43) Pub. Date: Oct. 2, 2025

(54) POWER CONVERSION DEVICE, METHOD OF CONTROLLING POWER CONVERSION DEVICE, SEMICONDUCTOR DEVICE, AND METHOD OF CONTROLLING SEMICONDUCTOR DEVICE

(71) Applicant: MINEBEA POWER SEMICONDUCTOR DEVICE INC., Hitachi-shi, Ibaraki (JP)

(72) Inventors: Mutsuhiro MORI, Tokyo (JP); Yusuke KANNO, Tokyo (JP); Tomoyasu FURUKAWA, Tokyo (JP); Tomoyuki MIYOSHI, Tokyo (JP)

(21) Appl. No.: 18/864,116

(22) PCT Filed: May 11, 2023
(86) PCT No.: PCT/JP2023/017766

§ 371 Date: Nov. 8, 2024

(30) Foreign Application Priority Data
May 13, 2022 (JP) 2022-079729

(51) Int. Cl. H10D 84/80; H02M 7/537; H03K 17/16; H10D 8/00; H10D 8/60; H10D 12/00; H10D 30/63; H10D 62/10; H10D 62/60; H10D 64/27

(52) U.S. Cl. CPC H10D 84/811; H02M 7/537; H03K 17/168; H10D 8/411; H10D 8/60; H10D 12/212; H10D 30/63; H10D 62/124; H10D 62/60; H10D 64/513; H10D 64/518

(57) ABSTRACT

A power conversion device configured to convert electric power using a semiconductor device includes a MOS controlled diode 1 made up of an n⁺ layer 11, an n⁻ layer 12, a p⁻ layer 13, a p⁺ layer 14, a cathode electrode 21, anode electrodes 22 and 220, and gate electrodes 23 and a voltage applying unit configured to apply forward voltage between the anode electrodes 22 and 220 and the cathode electrode 21 during a forward direction, to apply a reverse voltage between the anode electrodes 20 and 220 and the cathode electrode 21 during a reverse recovery, and to control a potential of the gate electrode 23 to a potential at which an inversion layer is formed in a third semiconductor layer with respect to a potential of the anode electrodes 22 and 220 before the reverse recovery. In this way, a power conversion device, a method of controlling a power conversion device, a semiconductor device, and a method of controlling a semiconductor device that are capable of further reducing power loss are provided.

### TECHNICAL FIELD

The present invention relates to a power conversion device, a method of controlling a power conversion device, a semiconductor device, and a method of controlling a semiconductor device. The present invention particularly relates to a power conversion device suitable for switching control of a large current.

### BACKGROUND ART

Currently, power conversion devices such as inverters and converters are widely used in a variety of appliances including home appliances such as air conditioners, refrigerators, and induction cookers, industrial and automotive equipment such as electric vehicles, uninterruptible power supplies, solar power generation, and wind power generation, and high-voltage high-power equipment such as railway and construction machinery, steelmaking, and power grids. A power conversion device is a device necessary for achieving energy conservation and new energy sources, and is a key component for realizing, for example, a decarbonized society. Therefore, it is necessary to widely disseminate power conversion devices, and it is desirable for them to be low-cost and small-sized such that they can be installed anywhere for that purpose.

In recent years, technological development capable of exceeding the low-loss limits of conventional IGBTs and pn diodes has been progressing by combining power semiconductors using Si, which has low material prices and can utilize the vast assets cultivated in LSIs, with the control of power conversion devices and by using innovative control techniques. For flywheel diodes which are major components of power conversion devices, MOS controlled diodes in which a MOS (Metal Oxide Semiconductor) gate is newly added to a conventional pn diode and the gate is controlled to achieve low loss have been announced.

Patent Document 1 describes a semiconductor device. In this semiconductor device, a semiconductor substrate side of a gate electrode provided on a surface of an anode electrode 22 side of a semiconductor substrate including silicon is surrounded by a p layer, an n layer, and a p layer via a gate insulating film. Also, the anode electrode is in contact with the p layer with low resistance and is also in contact with the n layer or the p layer, and a Schottky diode is formed between the anode electrode and the n layer or the p layer.

Non-Patent Document 1 describes a MOS controlled diode in which a MOS (Metal Oxide Semiconductor) gate is newly added to a conventional pn diode and the gate is controlled to achieve low loss.

### RELATED ART DOCUMENTS

### Patent Documents

Patent Document 1: Japanese Unexamined Patent Application Publication No. 2019-149511

Non-Patent Document 1: ISPSD (International Symposium on Power Semiconductor Devices & IC's), 2008, p. 40-43

### SUMMARY OF THE INVENTION

### Problems to be Solved by the Invention

A power conversion device generates power loss when controlling high-voltage and high-current power. This tends to result in larger cooling devices and higher costs. Therefore, how to reduce power loss has become an important issue for widely disseminating the use of power conversion devices.

Up until now, reduction of power loss in power conversion devices has been achieved primarily by reducing the loss in the power semiconductors used in those devices. However, the reduction of loss in IGBTs (Insulated Gate Bipolar Transistors) and pn diodes for flywheel diodes, which are currently the mainstream power semiconductors using silicon (Si), is reaching its limit. There are power conversion devices in which MOSFETS (Metal Oxide Semiconductor Field Effect Transistors) and Schottky diodes using silicon carbide (SiC) which has lower loss than Si are mounted, but the SiC material itself is expensive. Therefore, the full-scale adoption thereof to the wide range of power conversion devices necessary for the decarbonized society has not progressed.

An object of the present invention is to provide a power conversion device, a method of controlling a power conversion device, a semiconductor device, and a method of controlling a semiconductor device that are capable of further reducing power loss.

### Means for Solving the Problems

In order to solve the problems described above, the present invention provides a power conversion device configured to convert electric power using a semiconductor device, and the power conversion device includes: the semiconductor device including: a first semiconductor layer of a first conductivity type; a second semiconductor layer of the first conductivity type provided on one surface side of the first semiconductor layer and having an impurity concentration lower than that of the first semiconductor layer; a third semiconductor layer of a second conductivity type provided on the one surface side of the second semiconductor layer; a fourth semiconductor layer of the second conductivity type provided in contact with the third semiconductor layer and having an impurity concentration higher than that of the third semiconductor layer; a cathode electrode provided on the other surface side of the first semiconductor layer; an anode electrode provided on the one surface side of the third semiconductor layer and having a protruding portion in contact with the fourth semiconductor layer; and gate electrodes provided so as to interpose the protruding portion in a direction intersecting a direction in which the first semiconductor layer, the second semiconductor layer, and the third semiconductor layer are stacked and to be in contact with the third semiconductor layer via a gate insulating film; and a voltage applying unit configured to apply a forward voltage between the anode electrode and the cathode electrode during a forward direction, to apply a reverse voltage between the anode electrode and the cathode electrode during a reverse recovery, and to control a potential of the gate electrode to a potential at which an inversion layer is formed in the third semiconductor layer with respect to a potential of the anode electrode before the reverse recovery.

Also, the present invention is a method of controlling a power conversion device when operating the power conversion device configured to convert electric power using a semiconductor device, for the semiconductor device including: a first semiconductor layer of a first conductivity type; a second semiconductor layer of the first conductivity type provided on one surface side of the first semiconductor layer and having an impurity concentration lower than that of the first semiconductor layer; a third semiconductor layer of a second conductivity type provided on the one surface side of the second semiconductor layer; a fourth semiconductor layer of the second conductivity type provided in contact with the third semiconductor layer and having an impurity concentration higher than that of the third semiconductor layer; a cathode electrode provided on the other surface side of the first semiconductor layer; an anode electrode provided on the one surface side of the third semiconductor layer and having a protruding portion in contact with the fourth semiconductor layer; and gate electrodes provided so as to interpose the protruding portion in a direction intersecting a direction in which the first semiconductor layer, the second semiconductor layer, and the third semiconductor layer are stacked and to be in contact with the third semiconductor layer via a gate insulating film, the method performing control of applying a forward voltage between the anode electrode and the cathode electrode during a forward direction, applying a reverse voltage between the anode electrode and the cathode electrode during a reverse recovery, and controlling a potential of the gate electrode to a potential at which an inversion layer is formed in the third semiconductor layer with respect to a potential of the anode electrode before the reverse recovery, thereby operating the power conversion device.

Further, the present invention provides a semiconductor device including: a first semiconductor layer of a first conductivity type; a second semiconductor layer of the first conductivity type provided on one surface side of the first semiconductor layer and having an impurity concentration lower than that of the first semiconductor layer; a third semiconductor layer of a second conductivity type provided on the one surface side of the second semiconductor layer; a fourth semiconductor layer of the second conductivity type provided in contact with the semiconductor and having third layer an impurity concentration higher than that of the third semiconductor layer; a cathode electrode provided on the other surface side of the first semiconductor layer; an anode electrode provided on the one surface side of the third semiconductor layer and having a protruding portion in contact with the fourth semiconductor layer; and gate electrodes provided so as to interpose the protruding portion in a direction intersecting a direction in which the first semiconductor layer, the second semiconductor layer, and the third semiconductor layer are stacked and to be in contact with the third semiconductor layer via a gate insulating film.

Furthermore, the present invention provides a semiconductor device including: a first semiconductor layer of a first conductivity type; a second semiconductor layer of the first conductivity type provided on one surface side of the first semiconductor layer and having an impurity concentration lower than that of the first semiconductor layer; a third semiconductor layer of a second conductivity type provided on the one surface side of the second semiconductor layer; a fourth semiconductor layer of the second conductivity type provided in contact with the third semiconductor layer and having an impurity concentration higher than that of the third semiconductor layer; a cathode electrode provided on the other surface side of the first semiconductor layer; an anode electrode provided on the one surface side of the third semiconductor layer and being in contact with the fourth semiconductor layer; and a gate electrode provided adjacent to the anode electrode and the fourth semiconductor layer.

Still furthermore, the present invention provides a method of controlling a semiconductor device, for the semiconductor device including: a first semiconductor layer of a first conductivity type; a second semiconductor layer of the first conductivity type provided on one surface side of the first semiconductor layer and having an impurity concentration lower than that of the first semiconductor layer; a third semiconductor layer of a second conductivity type provided on the one surface side of the second semiconductor layer; a fourth semiconductor layer of the second conductivity type provided in contact with the third semiconductor layer and having an impurity concentration higher than that of the third semiconductor layer; a cathode electrode provided on the other surface side of the first semiconductor layer; an anode electrode provided on the one surface side of the third semiconductor layer and having a protruding portion in contact with the fourth semiconductor layer; and gate electrodes provided so as to interpose the protruding portion in a direction intersecting a direction in which the first semiconductor layer, the second semiconductor layer, and the third semiconductor layer are stacked and to be in contact with the third semiconductor layer via a gate insulating film, the method performing control of applying a forward voltage between the anode electrode and the cathode electrode during a forward direction, applying a reverse voltage between the anode electrode and the cathode electrode during a reverse recovery, and controlling a potential of the gate electrode to a potential at which an inversion layer is formed in the third semiconductor layer with respect to a potential of the anode electrode before the reverse recovery.

### Effects of the Invention

According to the present invention, it is possible to provide a power conversion device, a method of controlling a power conversion device, a semiconductor device, and a method of controlling a semiconductor device that are capable of further reducing power loss as compared with the case where the configuration of the present invention is not adopted.

### BRIEF DESCRIPTIONS OF THE DRAWINGS

FIG. 1 is a diagram illustrating an example of a cross-sectional structure of a MOS controlled diode mounted in a power conversion device according to a first embodiment of the present invention.

FIG. 2(a) is a diagram illustrating an example of an equivalent circuit of the MOS controlled diode in FIG. 1 with newly created symbols. (b) is a diagram illustrating an a equivalent circuit of MOS controlled diode proposed conventionally.

FIG. 3 is a diagram illustrating an example of a circuit symbol of a MOS controlled diode having the equivalent circuit in FIG. 2(a).

FIG. 4 is a diagram illustrating a gate voltage dependency of forward characteristics of the MOS controlled diode according to the first embodiment.

FIG. 5 is a diagram illustrating an example of a gate voltage dependency of the amount of charge accumulated in the MOS controlled diode according to the first embodiment.

FIG. 6 is a diagram illustrating an example of a circuit configuration of a power conversion device to which the MOS controlled diode according to the embodiment is applied.

FIG. 7 illustrates an example of operational waveforms during reverse recovery of each of the MOS controlled diode and the IGBT of the power conversion device in FIG. 6.

FIG. 8 is a diagram illustrating a gate voltage dependency of reverse recovery characteristics in the MOS controlled diode according to the embodiment.

FIG. 9 is a diagram illustrating an example of a cross-sectional structure of a MOS controlled diode mounted in a power conversion device according to a second embodiment of the present invention.

FIG. 10 is a diagram illustrating an example of a cross-sectional structure of a MOS controlled diode mounted in a power conversion device according to a third embodiment of the present invention.

FIG. 11 is a diagram illustrating an example of a cross-sectional structure of a MOS controlled diode mounted in a power conversion device according to a fourth embodiment of the present invention.

FIG. 12 is a diagram illustrating an example of a cross-sectional structure of a MOS controlled diode mounted in a power conversion device according to a fifth embodiment of the present invention.

FIG. 13 is a diagram illustrating an example of actually measured output characteristics of the MOS controlled diode mounted in the power conversion device according to the fifth embodiment of the present invention.

FIG. 14 is a diagram illustrating an example of a circuit configuration of a power conversion device according to a sixth embodiment of the present invention.

FIG. 15 is a diagram illustrating an example of a circuit configuration of a power conversion device according to a seventh embodiment of the present invention.

FIG. 16 is a diagram illustrating an example of a cross-sectional structure of a dual-gate IGBT.

FIG. 17 is a diagram illustrating an example of a circuit symbol indicating the dual-gate IGBT in FIG. 16.

FIG. 18 illustrates an example of drive waveforms (or drive signals) representing a method of controlling two Gc and Gs gates of a dual-gate IGBT and a Gd gate (gate electrode) of a MOS controlled diode in upper and lower arms of the power conversion device in FIG. 15.

### DETAILED DESCRIPTION OF PREFERRED EMBODIMENTS

Hereinafter, first to seventh embodiments of the present invention will be described in detail with reference to the accompanying drawings. Note that, in these drawings, expressions such as n⁻, n, and n⁺ mean that a semiconductor layer is n type and the impurity concentration becomes relatively higher in this order. Also, expressions such as p⁻, p, and p⁺ mean that a semiconductor layer is p type and the impurity concentration becomes relatively higher in this order. Further, in each drawing, common components are denoted by the same reference characters and duplicated descriptions are omitted.

### First Embodiment

First, a MOS controlled diode 1 according to the first embodiment will be described here. In the first embodiment, the MOS controlled diode 1 is configured such that a pn diode and an n channel MOSFET are connected in parallel between an anode (A) and a cathode (K) when the MOS controlled diode 1 is made into an equivalent circuit. In addition, a p⁻ layer 130 having a low impurity concentration is used for a source (S) of the MOSFET. Further, a first example of this configuration will be described in the first embodiment.

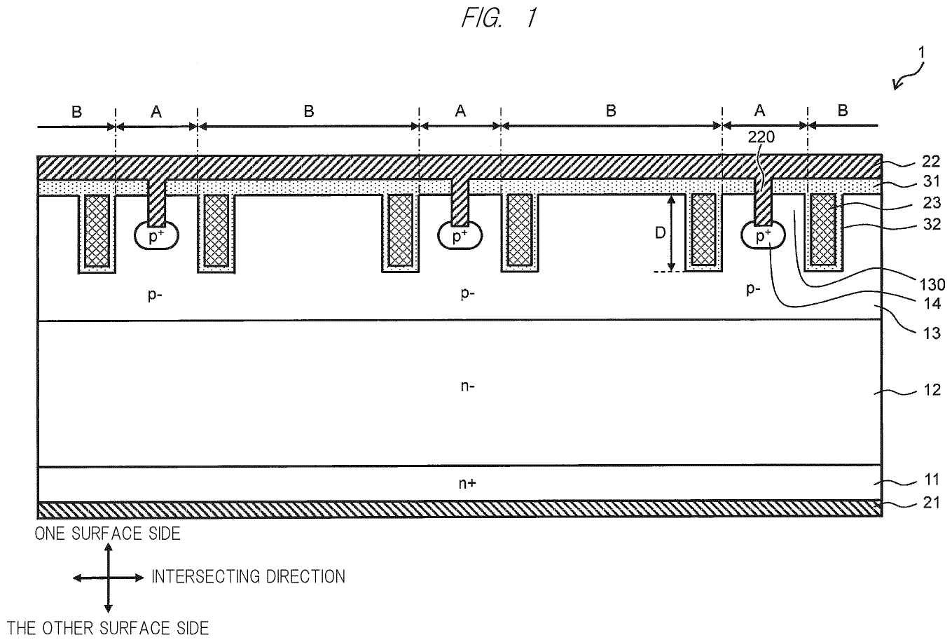

FIG. 1 is a diagram illustrating an example of a cross-sectional structure of the MOS controlled diode 1 mounted in a power conversion device according to the first embodiment of the present invention.

The illustrated MOS controlled diode 1 is an example of a semiconductor device. In FIG. 1, the upper side in the drawing is defined as one surface side. Also, the lower side in the drawing is defined as the other surface side. In other words, when considering a pair of main surfaces of a stacked body in which respective layers are stacked described below, the side of one main surface is defined as one surface side and the side of the other main surface is defined as the other surface side. Further, the left-right direction in the drawing is defined as a direction intersecting the stacking direction in which the respective layers are stacked. The intersecting direction is, for example, a direction perpendicular to the stacking direction.

As illustrated in FIG. 1, a semiconductor substrate of the MOS controlled diode 1 has a layer structure made up of an n⁺ layer 11, an n⁻ layer 12, p⁻ layers 13 and 130, and a p⁺ layer 14. In addition, the MOS controlled diode 1 includes, as electrodes, a cathode electrode 21, anode electrodes 22 and 220, and gate electrodes 23.

The n⁺ layer 11 is an example of a first semiconductor layer of a first conductivity type.

The n⁻ layer 12 is an example of a second semiconductor layer of the first conductivity type provided on the one surface side of the n+layer 11 and having an impurity concentration lower than that of the n⁺ layer 11.

The p⁻ layers 13 and 130 are an example of a third semiconductor layer of a second conductivity type provided on the one surface side of the n⁻ layer 12. Of these, the p⁻ layer 130 refers to a region interposed between gate insulating films 32 in the intersecting direction. In addition, the p⁻ layer 13 refers to the region on the other surface side relative to the p⁻ layer 130.

The p⁺ layer 14 is an example of a fourth semiconductor layer of the second conductivity type provided in the p⁻ layer 130 and having an impurity concentration higher than that of the p⁻ layers 13 and 130.

In this specification, the n type is the first conductivity type and the p type is the second conductivity type.

The cathode electrode 21 is provided on the other surface side of the n⁺ layer 11. The cathode electrode 21 is in electrical contact with the n⁺ layer 11 with low resistance.

The anode electrodes 22 and 220 are provided on the one surface side of the p-layers 13 and 130. The anode electrodes 22 and 220 are made up of the anode electrode 22 and the anode electrode 220. The anode electrode 22 is a layer-like portion provided on the one surface side of the p⁻ layers 13 and 130 via an insulating film 31. The anode electrode 220 is an example of a protruding portion, which protrudes from the layer-like anode electrode 22 into the p⁻ layer 130 to be in contact with the p⁺ layer 14. In the case of FIG. 1, the anode electrode 220 is also in contact with the p⁻ layer 130. In this case, it can also be said that the p⁺ layer 14 is disposed in the p⁻ layer 130 and is in contact with a tip portion of the anode electrode 220. Note that the anode electrode 220 is in electrical contact with the p⁺ layer 14 with low resistance.

The gate electrodes 23 are provided so as to be surrounded by the p⁻ layers 13 and 130 and interpose the anode electrode 220 therebetween in a direction intersecting the direction in which the n⁺ layer 11, the n⁻ layer 12, and the p⁻ layers 13 and 130 are stacked. In addition, the gate electrode 23 is in contact with the p⁻ layers 13 and 130 via the gate insulating film 32. Namely, the gate electrode 23 is insulated from the p⁻ layers 13 and 130 by the gate insulating film 32. In this case, it can also be said that the gate electrode 23 is provided adjacent to the anode electrode 220 and the p⁺ layer 14. Furthermore, in this case, it can also be said that the gate electrode 23 and the gate insulating film 32 form a trench structure. The gate electrode 23 and the p-layers 13 and 130 function as an n channel MOSFET (metal-oxide-semiconductor field-effect transistor).

Note that the insulating film 31 and the gate insulating film 32 are formed integrally. In FIG. 1, the distance by which the gate insulating film 32 protrudes from the insulating film 31 into the p⁻ layers 13 and 130 is defined as a depth D. Also, the p⁺ layer 14 is provided so as to fall within the depth D. This can also be said that the p⁺ layer 14 is formed inside a concave portion formed by the gate electrodes 23 and the gate insulating films 32. It can also be said that the p⁺ layer 14 is interposed between two adjacent trench structures each formed of the gate electrode 23 and the gate insulating film 32 and is formed inside a region between them.

Here, as illustrated in FIG. 1, a length between the gate insulating films 32 having the p⁺ layer 14 is defined as a distance A, and a length between the gate insulating films 32 having no p⁺ layer 14 is defined as a distance B. In this case, a structure that falls within a range including a pair of the distance A and the distance B in the intersecting direction in the drawing is referred to as a unit cell or a basic cell. The illustrated MOS controlled diode 1 has a structure in which this unit cell is repeatedly arranged in the intersecting direction (left-right direction, horizontal direction) in the drawing. In addition, in a depth direction of FIG. 1, the illustrated structure continues linearly. In other words, when the MOS controlled diode 1 is cut in the same direction as in FIG. 1, the same structure as in FIG. 1 appears no matter where it is cut.

In the MOS controlled diode 1, a forward voltage is applied between the anode electrodes 22 and 220 and the cathode electrode 21 during the forward direction by a voltage applying unit (not illustrated). Namely, a positive potential is applied to the anode electrodes 22 and 220 of the MOS controlled diode 1, and a negative potential is applied to the cathode electrode 21 thereof.

In this case, even when the potential of the gate electrode 23 is the same as that of the anode electrodes 22 and 220, the p⁺ layer 14, the p⁻ layer 13, and the n⁻ layer 12 are forward biased. Therefore, a large number of holes are injected from the p⁺ layer 14 through the p⁻ layer 13 into the n⁻ layer 12. In other words, even if the MOSFET made up of the gate electrode 23 and the p⁻ layers 13 and 130 does not operate, holes are directly injected from the p⁺ layer 14 via the p⁻ layer 13. Then, these holes promote the injection of a large number of electrons from the n⁺ layer 11 in contact with the cathode electrode 21 into the n⁻ layer 12, and the n-layer 12 is brought into a state in which a large amount of holes and electrons are accumulated. These electrons flow into the p⁻ layer 13 and promote further hole injection from the p⁺ layer 14. As a result, the n⁻ layer 12 is subjected to conductivity modulation to a low resistance, and the forward voltage of the MOS controlled diode 1 decreases.

In the MOS controlled diode 1 according to this embodiment, a current flows in the order of the p⁺ layer 14, the p⁻ layer 13, the n⁻ layer 12, and the n⁺ layer 11 to form a current path. Also, in the MOS controlled diode 1, no MOSFET is added in series to this current path. Therefore, as compared with a conventional MOS controlled diode in which a MOSFET is added in series to the current path, the forward voltage is further reduced, and the conduction loss is further reduced. Furthermore, by providing the p⁺ layer 14 so as to fall within the depth D, this effect becomes even more remarkable. In addition, by providing the region of the distance B, not only electrons injected from the n⁺ layer 11 in the region of the distance A, but also electrons injected from the n⁺ layer 11 in the region of the distance B flow into the anode electrode 220 in the region of the distance A, and hole injection from the p⁺ layer 14 is further promoted. In order to reduce the forward voltage, it is preferable to make the distance B larger than the distance A (A<B). This further promotes the conductivity modulation and reduces the forward voltage. This can also be said that the distance A of the p⁻ layer 13 in the intersecting direction between two adjacent gate electrodes 23 and gate insulating films 32 interposing the anode electrode 220 serving as a protruding portion therebetween is smaller than the distance B between two adjacent gate electrodes 23 and gate insulating films 32 interposing no anode electrode 220 therebetween.

On the other hand, when the MOS controlled diode 1 is to be reverse recovered to the blocking state after a forward current flows through it, a negative potential is applied to the anode electrodes 22 and 220 and a positive potential is applied to the cathode electrode 21 by a voltage applying unit (not illustrated). Namely, during reverse recovery, a reverse voltage is applied between the anode electrodes 22 and 220 and the cathode electrode 21. Further, in this embodiment, the potential of the gate electrode 23 is set to a positive potential relative to the potential of the anode electrodes 22 and 220 immediately before the reverse recovery. The time immediately before the reverse recovery is the time before starting the operation of the reverse recovery. In this way, an n inversion layer is formed at the interface of the p⁻ layers 13 and 130 in contact with the gate insulating film 32. Electrons flow more easily through this n inversion layer than the p⁻ layer 13. Therefore, electrons injected from the n⁻ layer 12 to the p⁻ layer 13 detour the p⁺ layer 14 and flow into the n inversion layer, and then flow into the anode electrode 220 via the p⁻ layer 130. As a result, the injection of holes from the p⁺ layer 14 is suppressed, and the accumulated charge of holes and electrons in the n⁻ layer 12 is drastically reduced. Therefore, when the MOS controlled diode 1 is reverse recovered afterward, the reverse recovery current decreases and the reverse recovery loss also decreases. Note that the control of setting the potential of the gate electrode 23 to a positive potential relative to the potential of the anode electrodes 22 and 220 may be continued even during the reverse recovery.

Furthermore, the MOS controlled diode 1 does not have an n⁺ layer on the side of the anode electrode as in the MOS controlled diode of the prior art, and the parasitic npn transistor effect is suppressed. Therefore, the reverse recovery safe operating area can be increased. Furthermore, by forming the gate electrode 23 to have the above-mentioned trench structure, the width of the trench bottom corresponding to the bottom portion of this trench structure is reduced. As a result, the MOS controlled diode 1 has both the characteristics that the channel length of the n inversion layer can be shortened and the parasitic npn transistor effect is less likely to occur.

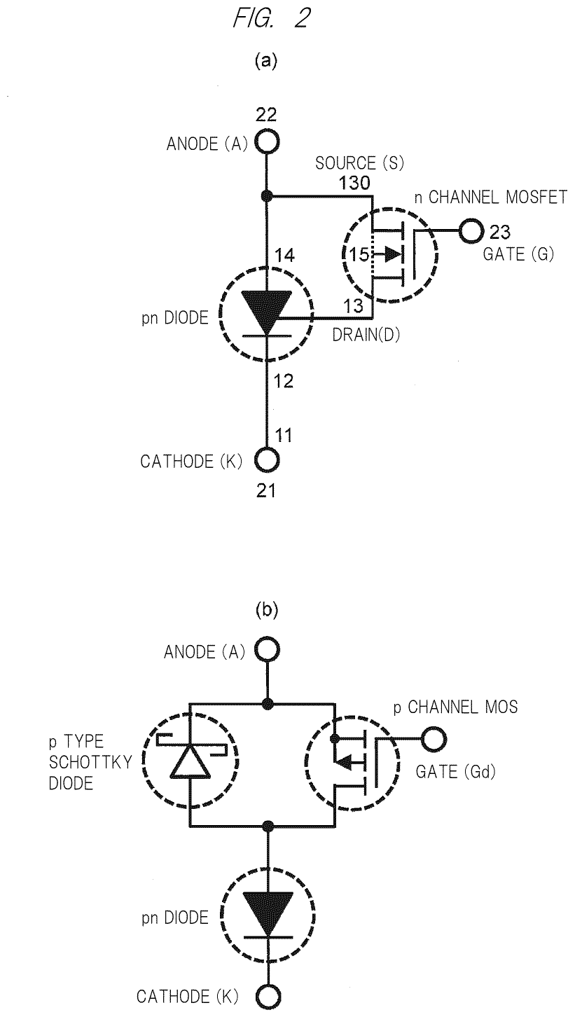

FIG. 2(a) is a diagram illustrating an example of an equivalent circuit of the MOS controlled diode 1 in FIG. 1 with newly created symbols.

Note that the numbers in FIG. 2(a) correspond to the reference characters in FIG. 1. In this case, the pn diode and the n channel MOSFET are connected in parallel between the anode (A) and the cathode (K). In this case, the pn diode corresponds to n⁺ layer 11, the n⁻ layer 12, the p⁻ layer 13, and the p⁺ layer 14. Also, the n channel MOSFET corresponds to the gate electrode 23 and the p⁻ layer 130. In addition, the anode (A) corresponds to the anode electrodes 22 and 220. Further, the cathode (K) corresponds to the cathode electrode 21. Furthermore, a gate (G) corresponds to the gate electrode 23.

A drain (D) of the n channel MOSFET is connected from the middle of the p⁻ layer 13, and the source (S) is connected to the anode (A) via the p⁻ layer 130. In order to divert the current from the middle of the p⁻ layer 13 to the drain (D), the injection amount from the p⁺ layer 14 to the p⁻ layers 13 and 130 can be controlled by the gate (G), and the electrical conductivity of the MOS controlled diode 1 during the forward direction and the reverse recovery can be adjusted.

In contrast, FIG. 2(b) is a diagram illustrating an equivalent circuit of a MOS controlled diode proposed conventionally.

In the MOS controlled diode in FIG. 2(b), a pn diode and a p channel MOSFET are connected in series. Namely, a p channel MOSFET is added in series to a pn diode current path. In this case, during the forward direction, the forward voltage increases more and the conduction loss is larger than those in the MOS controlled diode 1 illustrated in FIG. 2(a). Further, during the reverse recovery, the reverse recovery current increases more and the reverse recovery loss is also larger than those in the MOS controlled diode 1 illustrated in FIG. 2(a). This can also be said that the MOS controlled diode 1 illustrated in FIG. 2(a) can reduce forward voltage and conduction loss during the forward direction as compared with the MOS controlled diode proposed conventionally. It can also be said that the MOS controlled diode 1 illustrated in FIG. 2(a) can reduce reverse recovery current and reverse recovery loss during the reverse recovery as compared with the MOS controlled diode proposed conventionally.

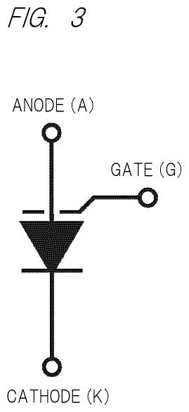

FIG. 3 is a diagram illustrating an example of a circuit symbol of the MOS controlled diode 1 having the equivalent circuit in FIG. 2(a).

This circuit symbol is newly created for the convenience of describing the embodiment. This circuit symbol is used not only for the MOS controlled diode 1 illustrated in FIG. 1, but also for the embodiments described later.

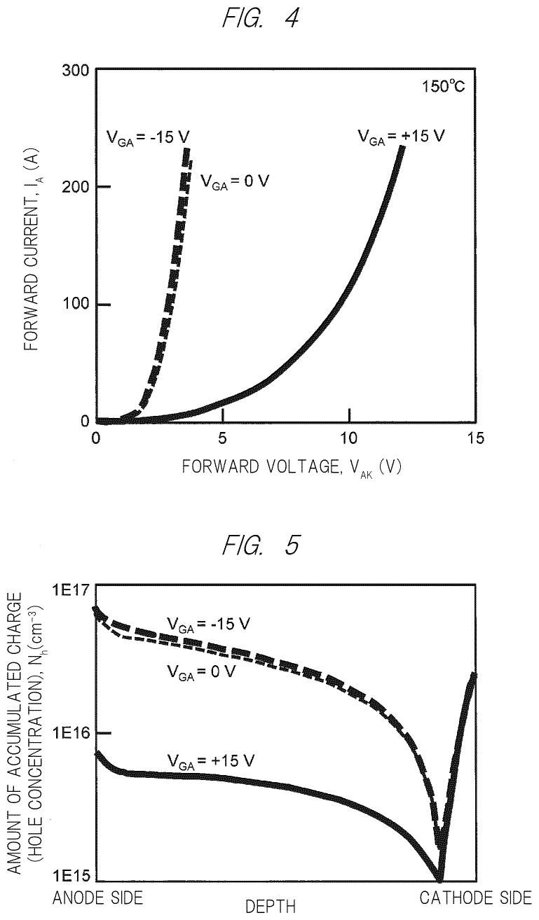

FIG. 4 is a diagram illustrating a gate voltage dependency of forward characteristics of the MOS controlled diode 1 according to the first embodiment. In FIG. 4, the horizontal axis represents the forward voltage, and the vertical axis represents the forward current.

As illustrated in FIG. 4, even when no voltage is applied, that is, the gate voltage (V_{GA}) between the gate and anode is 0 V, conductivity modulation is promoted and the forward voltage when the forward current is 200 A becomes 3.5 V. On the other hand, when the gate voltage (V_{GA}) is set to +15 V, the n channel MOSFET operates and the conductivity modulation decreases. As a result, the forward voltage when the forward current is 200 A increases to 12 V. The gate power supply that drives the gate voltage (V_{GA}) at 0 V and +15 V can be the same power supply as that of the IGBT described later. Therefore, the MOS controlled diode 1 according to this embodiment has the characteristics that the number of power supplies can be reduced and the gate circuit can be simplified and made smaller as compared with the conventional art in which the third −15 V is indispensable. Note that it is also possible to set the gate voltage (V_{GA}) to −15 V during the forward direction. In this case, a p accumulation layer is formed at the interface of the p⁻ layers 13 and 130 in contact with the gate insulating film 32. This further reduces the forward voltage as illustrated in FIG. 4. Note that this control may be performed not only during the forward direction but also during the reverse blocking after the reverse recovery. Therefore, in this embodiment, it can be said that, during at least one of the forward direction and the reverse blocking after the reverse recovery, the potential difference between the gate electrode 23 and the anode electrodes 22 and 220 is set to 0 V, or the potential of the gate electrode 23 is controlled to be a potential opposite to the potential at which an inversion layer is formed in the third semiconductor layer with respect to the potential of the anode electrodes 22 and 220. In this case, the opposite potential is a negative potential (−15 V in the above-described case).

FIG. 5 is a diagram illustrating an example of a gate voltage dependency of the amount of charge accumulated in the MOS controlled diode 1 according to the first embodiment. In FIG. 5, the horizontal axis represents the depth, and the vertical axis represents the amount of accumulated charge.

Note that the amount of accumulated charge illustrated in FIG. 5 is a hole concentration, and is a value obtained by simulation calculation assuming the forward current of 200 A. It can be seen from FIG. 5 that, by setting the gate voltage to +15 V (V_{GA}), the amount of charge accumulated on the anode side in particular is reduced by about one order of magnitude as compared with the case where the gate voltage is 0 V or −15 V. In other words, in the conduction state, the conduction loss can be reduced by setting the gate voltage (V_{GA}) to 0 V or −15 V to lower the forward voltage. On the other hand, during the reverse recovery, the reverse recovery loss can be reduced by switching the gate voltage (V_{GA}) to +15 V immediately before the reverse recovery to reduce the amount of accumulated charge and reduce the reverse recovery current.

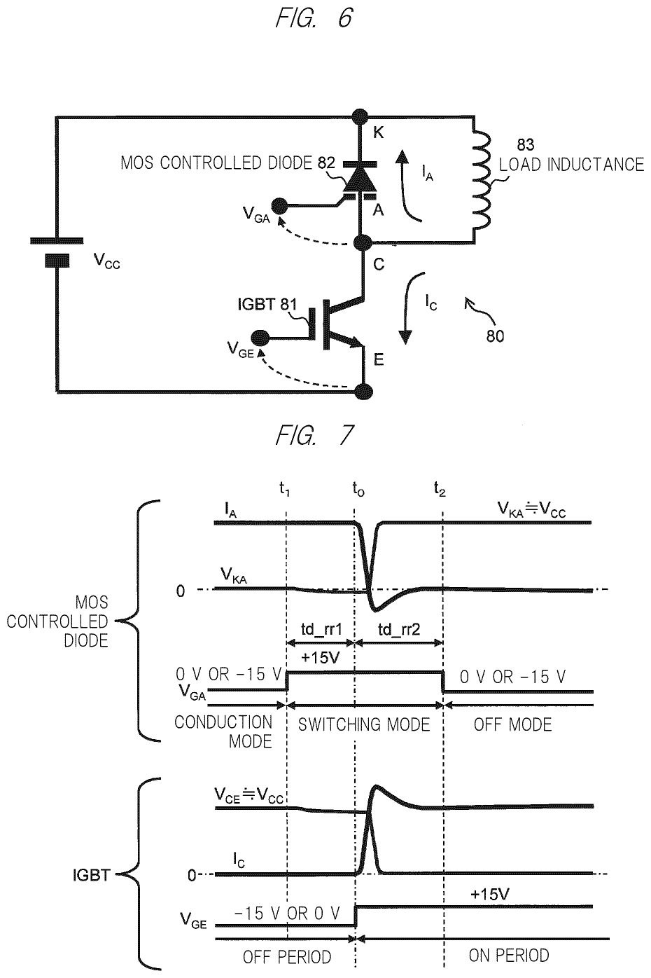

FIG. 6 is a diagram illustrating an example of a circuit configuration of a power conversion device 80 to which a MOS controlled diode 82 according to this embodiment is applied. Note that the MOS controlled diode 82 is indicated here by the circuit symbol for the MOS controlled diode illustrated in FIG. 3. Moreover, the MOS controlled diode 82 has a configuration similar to that of the MOS controlled diode 1 described above.

As illustrated in FIG. 6, the power conversion device 80 has the MOS controlled diode 82 and an IGBT 81 connected in series as an upper arm and a lower arm, respectively. The power conversion device 80 also has a load inductance 83 connected in parallel to the MOS controlled diode 82 as a chopper circuit. The power conversion device 80 adjusts the current flowing through the load inductance 83 and adjusts the power output amount by turning on and off a gate voltage (V_{GE}) of the IGBT 81.

Here, when the gate voltage (V_{GE}) of the IGBT 81 is turned on, a current supplied from a power supply (Vcc) flows through the load inductance 83 and a current (I_{C}) flows to the IGBT 81. Thereafter, when this current (I_{C}) reaches a desired value, the IGBT 81 is turned off. Then, the current (I_{C}) flows to the MOS controlled diode 82 as a current (I_{A}). This current (I_{A}) is consumed by the loss of the MOS controlled diode 82 and the parasitic resistance present in the circuit, and gradually decreases. Then, when the current (I_{A}) reaches the preset lower limit value, the IGBT 81 is turned on again to increase the current supplied to the load inductance 83, thereby maintaining the amount of current within the desired range.

FIG. 7 illustrates an example of operational waveforms during reverse recovery of each of the MOS controlled diode 82 and the IGBT 81 of the power conversion device 80 in FIG. 6.

Here, it is assumed that the IGBT 81 of the lower arm is turned on at time t₀.

In this case, the MOS controlled diode 82 of the upper arm switches the gate voltage V_{GA} from 0 V or −15 V to +15 V at time t₁ which is earlier than time t₀ by a charge extraction period td_rr1, thereby reducing the charge accumulated in the MOS controlled diode 82. This corresponds to the above-mentioned operation of “setting the potential of the gate electrode 23 to a positive potential relative to the potential of the anode electrodes 22 and 220 immediately before the reverse recovery”. Then, with the gate voltage (V_{GA}) remaining at +15 V, the IGBT 81 of the lower arm is turned on at time t₀, whereby the MOS controlled diode 82 of the upper arm is reverse recovered. At this time, the gate voltage V_{GA} of the MOS controlled diode 82 of the upper arm remains at +15 V. This corresponds to the above-mentioned operation of “setting the potential of the gate electrode 23 to a positive potential relative to the potential of the anode electrodes 22 and 220 during the reverse recovery”.

Subsequently, when time t₀ has passed and a reverse bias starts to be applied to the MOS controlled diode 82, the gate voltage (V_{GA}) of the MOS controlled diode 82 is switched from +15 V to 0 V or −15 V again at an arbitrary time t₂. The MOS controlled diode 82 stands by so as to be able to respond when the IGBT 81 of the lower arm is next turned off and current is commutated to the MOS controlled diode 82.

Note that the minimum value of a recovery period td_rr2 from when the IGBT 81 is turned on to when the gate voltage (V_{GA}) of the MOS controlled diode 82 becomes 0 V or −15 V again can be shortened until a reverse bias starts to be applied to the MOS controlled diode 82. By shortening this time, the n inversion layer of the n channel MOSFET can be eliminated before a large reverse bias voltage is applied, and the parasitic npn transistor effect can be eliminated. As a result, the reverse recovery safe operating area can be further increased.

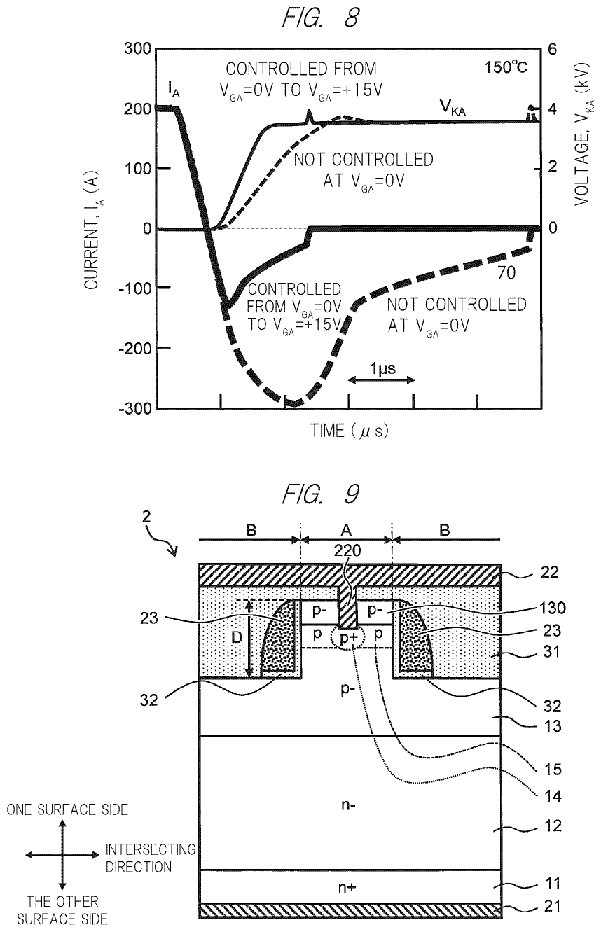

FIG. 8 is a diagram illustrating a gate voltage dependency of reverse recovery characteristics in the MOS controlled diode 82 according to the embodiment. In FIG. 8, the horizontal axis represents time and the vertical axis represents voltage.

FIG. 8 illustrates a voltage (V_{KA}) between the cathode (K) and the anode (A) and an anode current (I_{A}). Also, the solid line indicates the case where the gate voltage (V_{GA}) described in FIG. 6 and FIG. 7 is controlled from 0 V to +15 V at time t₁ immediately before the reverse recovery. On the other hand, the dashed line indicates the case where this control is not performed and the reverse recovery is performed without switching the voltage from 0 V.

By controlling the gate voltage from 0 V to +15 V, the amount of accumulated charge decreases as illustrate in FIG. 5. As a result, the reverse recovery current is significantly reduced as indicated by the solid line. Thus, it can be seen that the reverse recovery loss is dramatically reduced to 15% as compared with the case where the reverse recovery is performed with the gate voltage remaining at 0 V without performing this control (case indicated by dashed line).

### Second Embodiment

Next, a MOS controlled diode 2 according to the second embodiment will be described. In the second embodiment, similarly to the first embodiment, the MOS controlled diode 2 is configured such that a pn diode and an n channel MOSFET are connected in parallel between the anode (A) and the cathode (K) in an equivalent circuit. In addition, a p⁻ layer 130 having a low impurity concentration is used for the source (S) of the MOSFET. Also, in the second embodiment, a second example of this configuration will be described.

FIG. 9 is a diagram illustrating an example of a cross-sectional structure of the MOS controlled diode 2 mounted in a power conversion device according to the second embodiment of the present invention.

The MOS controlled diode 2 according to the second embodiment has a layer structure made up of the n⁺ layer 11, the n⁻ layer 12, the p⁻ layers 13 and 130, and the p⁺ layer 14 similarly to the first embodiment. Also, the MOS controlled diode 2 includes, as electrodes, the cathode electrode 21, the anode electrodes 22 and 220, and the gate electrode 23 similarly to the first embodiment.

On the other hand, in the MOS controlled diode 2, a p layer 15 is formed in at least a part of the p⁻ layer 130. The p layer 15 is an example of a fifth semiconductor layer of the second conductivity type. The p layer 15 is provided in the p⁻ layer 130 so as to interpose the anode electrode 220 in the intersecting direction described above. In the illustrated example, the p layer 15 is provided to divide the p⁻ layer 130 into two upper and lower layers as illustrated in the drawing. Namely, in this case, the n⁺ layer 11, the n⁻ layer 12, the p⁻ layer 13, the p⁻ layer 130, the p⁺ layer 14, the p layer 15, and the p⁻ layer 130 are stacked in this order. Further, the p⁻ layer 130 is divided into two layers such as the p⁻ layer 130 located on the one surface side and the p⁻ layer 130 located on the other surface side. The impurity concentration of the p layer 15 is higher than those of the p⁻ layers 13 and 130 and is lower than that of the p⁺ layer 14. In this way, the current of electrons flowing from the p⁻ layer 13 to the p⁻ layer 130 when a forward current flows is suppressed by the p layer 15, and hole injection from the p⁺ layer 14 and the p layer 15 is increased. As a result, the forward voltage is further reduced.

FIG. 2(a) also illustrates the p layer 15. In the equivalent circuit illustrated in FIG. 2(a), the p layer 15 functions as follows.

That is, for electrons flowing from the p⁻ layer 13 to the p⁻ layer 130, the barrier becomes higher by inserting the p layer 15. Also, the forward bias effect of the p layer 15 and the p⁺ layer 14 is increased by the height of the barrier (potential difference), and hole injection from the p layer 15 and the p⁺ layer 14 is promoted. As a result, the forward voltage is further reduced.

Moreover, the gate threshold voltage of the n channel MOSFET can be adjusted to a desired value by adjusting the concentration of the p layer 15.

In order to enhance the effect of suppressing the electron current flowing from the p⁻ layer 13 to the p⁻ layer 130 by the p layer 15, it is preferable to form the p layer 15 so as to span from the p⁺ layer 14 to the gate insulating film 32. This can also be said that the p layer 15 is preferably formed so as to connect the p⁺ layer 14 and the gate insulating film 32. In this way, since it is possible to suppress electron current from detouring over the entire boundary region of the p⁻ layer 13 and the p⁻ layer 130, the forward voltage is further reduced.

The impurity concentration of the p layer 15 is desirably set to such a degree that an n inversion layer is formed at the interface of the gate insulating film 32 in contact with the p layer 15 when the gate voltage (V_{GA}) of, for example, +15 V is applied to the gate electrode 23. In this way, the reduction of the accumulated charge immediately before the reverse recovery and the reduction of the reverse recovery loss during reverse recovery are not impaired.

Furthermore, the structure of the gate electrode 23 of the MOS controlled diode 2 is different from that of the MOS controlled diode 1. In this case, the gate electrode 23 becomes thicker in the intersecting direction described above as getting closer to the other surface side. This can also be said that the thickness of the gate electrode 23 increases in the direction from the one surface side to the other surface side. In this way, the gate capacitance is reduced by, for example, half, making it easier to drive the MOS controlled diode 2. This gate structure is referred to as a sidewall gate structure. It goes without saying that this sidewall gate structure can also be used for the MOS controlled diode 1. On the other hand, the gate structure of the MOS controlled diode 1 is referred to as a trench gate structure. Namely, in the trench gate structure, the thickness of the gate electrode is almost constant in the up-down direction in the drawing. Also, it is a matter of course that the trench gate structure of the MOS controlled diode 1 may be applied to the MOS controlled diode 2.

### Third Embodiment

Next, a MOS controlled diode 3 according to the third embodiment will be described. In the third embodiment, similarly to the first and second embodiments, the MOS controlled diode 3 is configured such that a pn diode and an n channel MOSFET are connected in parallel between the anode (A) and the cathode (K) in an equivalent circuit. In addition, an n layer 131 having a low impurity concentration is used for the source (S) of the MOSFET. Also, in the third embodiment, a third example of this configuration will be described.

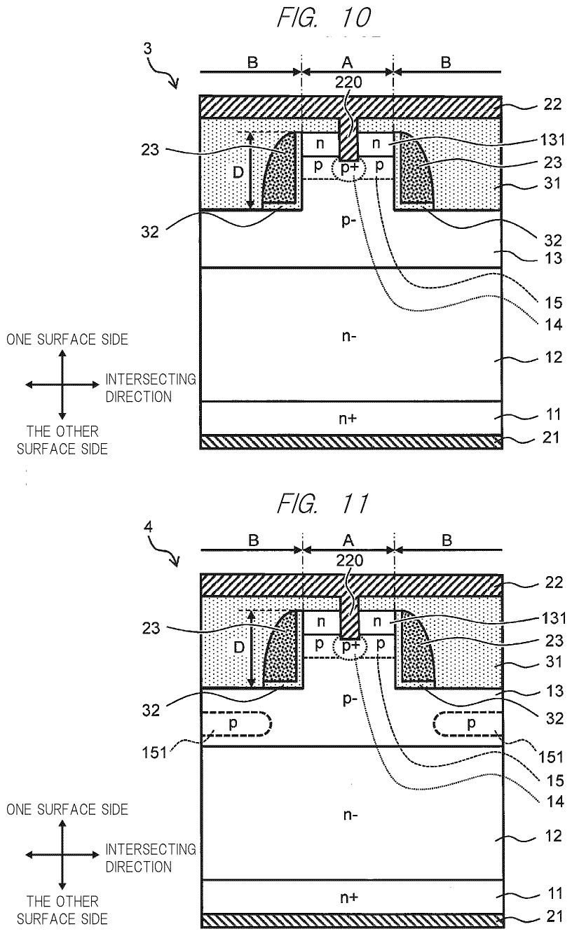

FIG. 10 is a diagram illustrating an example of a cross-sectional structure of the MOS controlled diode 3 mounted in a power conversion device according to the third embodiment of the present invention.

The MOS controlled diode 3 according to the third embodiment has a layer structure made up of the n⁺ layer 11, the n⁻ layer 12, the p⁻ layer 13, and the p⁺ layer 14 similarly to the first and second embodiments. Also, the MOS controlled diode 3 includes, as electrodes, the cathode electrode 21, the anode electrodes 22 and 220, and the gate electrode 23 similarly to the first and second embodiments.

On the other hand, in the MOS controlled diode 3 according to the third embodiment, as compared with the MOS controlled diode 2, the n layer 131 is formed instead of the p⁻ layer 130 located on the one surface side relative to the p layer 15. In this case, it can also be said that the n layer 131 located on the one surface side relative to the p layer 15 is formed. Namely, in this case, the n⁺ layer 11, the n⁻ layer 12, the p⁻ layer 13, the p⁺ layer 14, the p layer 15, and the n layer 131 are stacked in this order. The n layer 131 is an example of a sixth semiconductor layer of the first conductivity type. In this way, electrons flowing from the n inversion layer immediately before or during the reverse recovery are more likely to flow to the n layer 131 in which electrons are majority carriers as compared with the case of the p⁻ layer 130. As a result, the charge accumulated in the n⁻ layer 12 during the forward direction is reduced, and the reverse recovery loss is further reduced.

The impurity concentration of the n layer 131 is higher than that of the p⁻ layer 13 and lower than that of the p⁺ layer 14. Also, the impurity concentration of the n layer 131 is preferably lower than that of the p layer 15. In this way, the current amplification factor of the parasitic npn transistor made up of the n layer 131, the p layer 15, the p⁻ layer 13, the n⁻ layer 12, and the n⁺ layer 11 is reduced, making it possible to prevent the reduction in the reverse recovery safe operating area due to the operation of the parasitic npn transistor.

### Fourth Embodiment

Next, a MOS controlled diode 4 according to the fourth embodiment will be described. In the fourth embodiment, similarly to the first to third embodiments, the MOS controlled diode 4 is configured such that a pn diode and an n channel MOSFET are connected in parallel between the anode (A) and the cathode (K) in an equivalent circuit. In addition, the p⁻ layer 130 having a low impurity concentration is used for the source (S) of the MOSFET. Also, in the fourth embodiment, a fourth example of this configuration will be described.

FIG. 11 is a diagram illustrating an example of a cross-sectional structure of the MOS controlled diode 4 mounted in a power conversion device according to the fourth embodiment of the present invention.

The MOS controlled diode 4 according to the fourth embodiment has a layer structure made up of the n⁺ layer 11, the n⁻ layer 12, the p⁻ layer 13, and the p⁺ layer 14 similarly to the first to third embodiments. Also, the MOS controlled diode 4 includes, as electrodes, the cathode electrode 21, the anode electrodes 22 and 220, and the gate electrode 23 similarly to the first to third embodiments.

On the other hand, in the MOS controlled diode 4, as compared with the MOS controlled diode 3 in FIG. 10, a p layer 151 is provided in the p⁻ layer 13 on the other surface side relative to the gate electrode 23. The p layer 151 is an example of a seventh semiconductor layer of the second conductivity type. The impurity concentration of the p layer 151 is higher than that of the p⁻ layer 13. In this way, it is possible to suppress the electron current that has passed through the n layer 131 (or the p⁻ layer 130) and the n inversion layer during the reverse recovery from being injected from the n inversion layer into the p⁻ layer 13. In other words, the parasitic npn transistor made up of the n inversion layer, the p⁻ layer 13, and the n⁻ layer 12 becomes less likely to operate, and the reverse recovery safe operating area is significantly improved. In this embodiment, the p layer 151 and the p layer 15 can be formed simultaneously by the same ion implantation, and it is thus unnecessary to add a new manufacturing process for forming the p layer 151.

The junction between the p⁻ layer 130 (or n layer 131) and the anode electrode 220 illustrated in each of the MOS controlled diodes 1 to 4 is preferably the Schottky junction.

In the case of the p⁻ layer 130, the p⁻ layer 130 and the anode electrode 220 form a p type Schottky junction, and when reducing the accumulated charge immediately before the reverse recovery, the height of the barrier makes it easier for electrons to flow smoothly from the p-layer 130 to the anode electrode 220. As a result, the conductivity modulation of the n⁻ layer 12 can be further reduced.

On the other hand, in the case of the n layer 131, the n layer 131 and the anode electrode 220 form an n type Schottky junction, and the height of the barrier can reduce the flow of electrons into the n layer 131, thereby suppressing the operation of the parasitic npn transistor during the reverse recovery. As a result, the reverse recovery safe operating area can be improved. In this embodiment, the p layer 151 and the p layer 15 can be formed simultaneously by the same ion implantation, and it is thus unnecessary to add a new manufacturing process for forming the p layer 151.

### Fifth Embodiment

FIG. 12 is a diagram illustrating an example of a cross-sectional structure of a MOS controlled diode 3 mounted in a power conversion device according to the fifth embodiment of the present invention.

In the MOS controlled diode 3 according to the fifth embodiment, an n⁺ layer 132 having an impurity concentration higher than that of the p layer 15 is formed instead of the n layer 131 illustrated in the third and fourth embodiments. In this case, it can be said that the n⁺ layer 132 located on the one surface side relative to the p layer 15 is formed. The n⁺ layer 132 is also an example of the sixth semiconductor layer of the first conductivity type.

Even when the n⁺ layer 132 is in ohmic junction with the anode electrode 220, the contact resistance is lower as compared with the case of Schottky junction. In other words, it can be said that the n⁺ layer 132 located on the one surface side relative to the p layer 15 and in contact with the anode electrode 220 with lower resistance as compared with the case of Schottky junction is provided. Since the n⁺ layer 132 is in contact with the anode electrode 220 with lower resistance as compared with the case of Schottky junction, when the accumulated charge is reduced immediately before the reverse recovery, electrons flowing through the n inversion layer formed on the surface of the p⁻ layer 13 and the p layer 15 on the side of the gate electrode 23 can flow smoothly into the anode electrode 220 via the n⁺ layer 132. Therefore, more amount of accumulated charge is reduced, and the output characteristics of the MOS controlled diode 3 can be controlled to a greater extent by the gate voltage. As a result, the reverse recovery loss is further reduced.

In addition, by using the n⁺ layer 132 having an impurity concentration higher than that of the n layer 131, the parasitic npn transistor made up of the n⁺ layer 132, the p layer 15/p⁻ layer 13, and the n⁻ layer 12 becomes more likely to operate during the reverse recovery, but the operation of the parasitic npn transistor can be prevented by miniaturizing the n⁺ layer 132 and appropriately increasing the impurity concentration of the p layer 15 and the p⁻ layer 13.

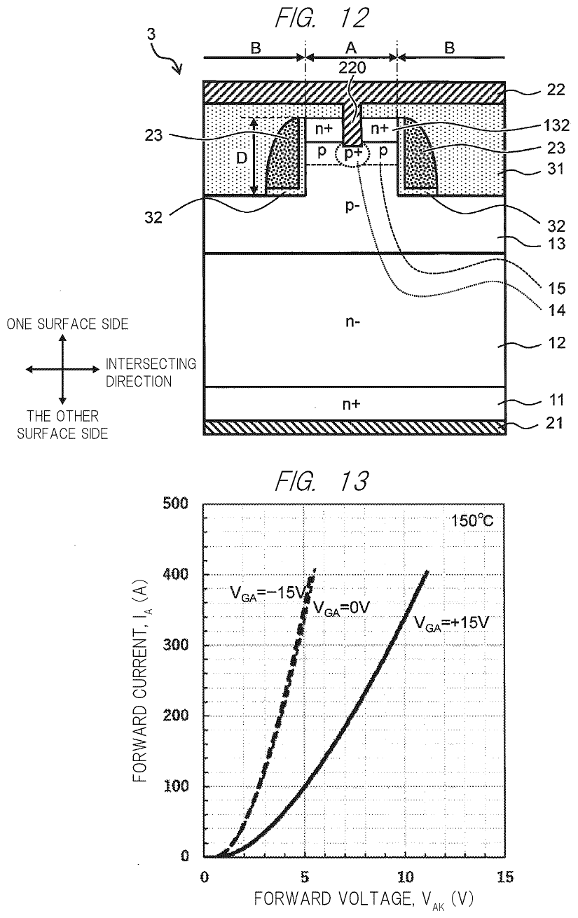

FIG. 13 illustrates an example of actually measured output characteristics of the MOS controlled diode 3 mounted in the power conversion device according to the fifth embodiment of the present invention illustrated in FIG. 12. It can be seen that the output characteristics of the MOS controlled diode 3 can be controlled by changing the gate voltage V_{GA}. In addition, since the output characteristics in the case of V_{GA}=−15 V and in the case of V_{GA}=0 V are almost the same, the output characteristics of the MOS controlled diode 3 can be controlled not only between V_{GA}=−15 V and V_{GA}=+15 V, but also between V_{GA}=0 V and V_{GA}=+15 V, making it unnecessary to provide a gate power supply for V_{GA}=−15V.

### Sixth Embodiment

Next, the sixth embodiment will be described. In the sixth embodiment, a power conversion device 1000 will be described as a first example of a power conversion device using the above-mentioned MOS controlled diode 82.

FIG. 14 is a diagram illustrating an example of a circuit configuration of the power conversion device 1000 according to the sixth embodiment of the present invention.

The illustrated power conversion device 1000 includes a DC/AC conversion circuit and the MOS controlled diode 82. This MOS controlled diode 82 may be any of the above-mentioned MOS controlled diodes 1 to 4, and is referred to as the MOS controlled diode 82 as a representative. The DC/AC conversion circuit is configured by connecting a plurality of IGBTs 81 (two in FIG. 14) that turn on and off the current in series between a pair of DC terminals 1010 and 1020. Also, AC terminals 1030, 1040, and 1050 are connected between the plurality of IGBTs 81. Further, in the power conversion device 1000, the MOS controlled diode 82 is connected in anti-parallel to each of the plurality of IGBTs 81.

The MOS controlled diode 82 of the power conversion device 1000 according to this embodiment may be any of the MOS controlled diodes 1 to 4 having the structures illustrated in FIG. 1 and FIG. 9 to FIG. 11. In FIG. 14, the MOS controlled diode 82 is indicated by the circuit symbol illustrated in FIG. 3.

Since the MOS controlled diode 82 is mounted in the power conversion device 1000, the conduction loss and reverse loss are reduced as compared with the case where a normal pn diode is used. Furthermore, the turn-on current of the IGBT 81 due to the reduction in the reverse recovery current is also reduced. As a result, it is possible to reduce loss in the inverter, that is, to achieve higher efficiency of the power conversion device 1000.

### Seventh Embodiment

Next, the seventh embodiment will be described. In the seventh embodiment, a power conversion device 1100 will be described as a second example of the power conversion device using the above-mentioned MOS controlled diode 82.

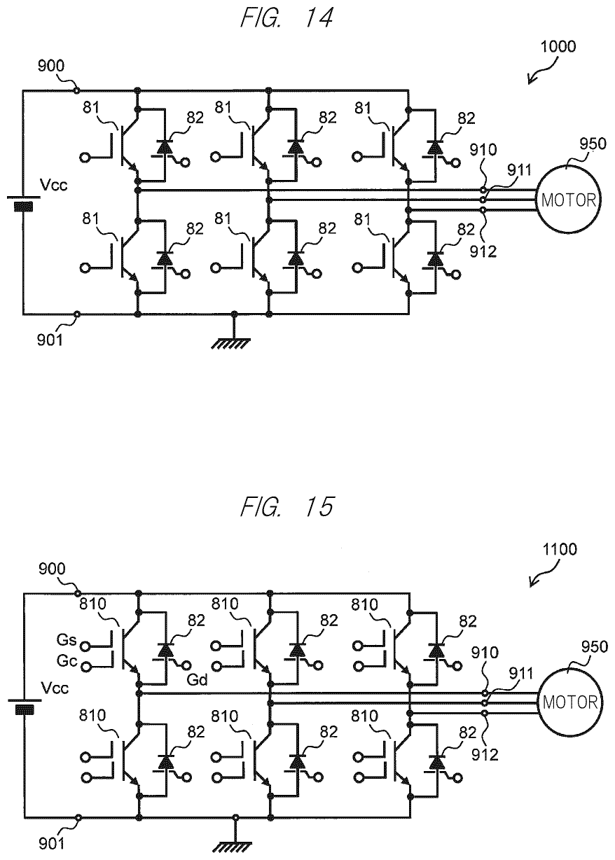

FIG. 15 is a diagram illustrating an example of a circuit configuration of the power conversion device 1100 according to the seventh embodiment of the present invention.

The power conversion device 1100 according to this embodiment is obtained by replacing the IGBT 81 with a dual-gate IGBT 810 in the circuit configuration of the power conversion device 1000 according to the sixth embodiment illustrated in FIG. 14. Here, the dual-gate IGBT 810 refers to an IGBT having two gates that can be driven with a time difference. In other words, the dual-gate IGBT 810 has, as two gate electrodes, a first gate and a second gate which can be independently controlled to be turned on and off.

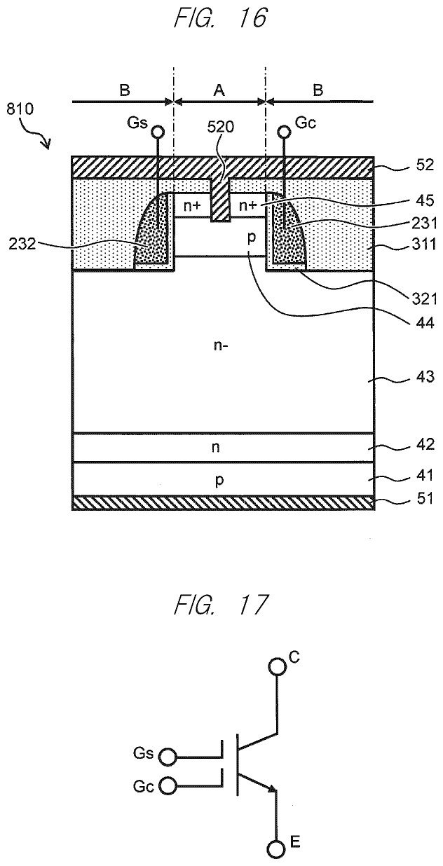

FIG. 16 is a diagram illustrating an example of a cross-sectional structure of the dual-gate IGBT 810.

The illustrated dual-gate IGBT 810 has a layer structure made up of a p layer 41, an n layer 42, an n⁻ layer 43, a p layer 44, and an n⁺ layer 45. The dual-gate IGBT 810 also includes, as electrodes, a cathode electrode 51, anode electrodes 52 and 520, and a Gc gate 231 and a Gs gate 232 as gate electrodes.

The anode electrodes 52 and 520 are made up of the anode electrode 52 and the anode electrode 520. The anode electrode 52 is a layer-like portion provided on the one surface side of the n⁻ layer 43 via an insulating film 311. The anode electrode 520 protrudes from the anode electrode 52 into the p layer 44 to be in contact with the p layer 44 and the n⁺ layer 45.

The Gc gate 231 and the Gs gate 232 are each provided so as to interpose the anode electrode 520 in a direction intersecting the direction in which the p layer 41, the n layer 42, the n⁻ layer 43, and the p layer 44 are stacked. Also, the Gc gate 231 and the Gs gate 232 are in contact with the n⁻ layer 43, the p layer 44, and the n⁺ layer 45 via a gate insulating film 321. The Gc gate 231 corresponds to the first gate, and the Gs gate 232 corresponds to the second gate.

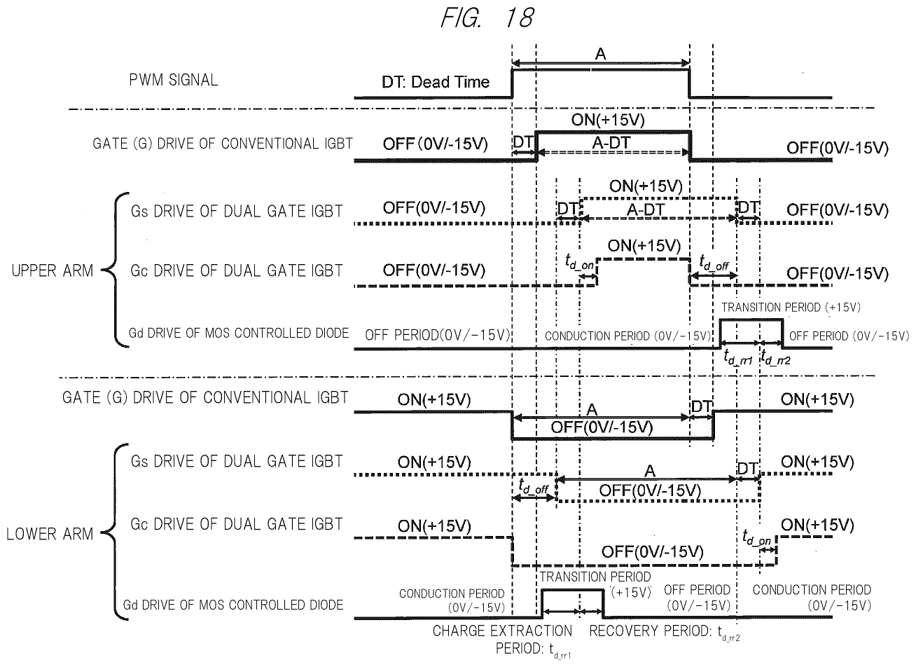

In the dual-gate IGBT 810 having the cross-sectional structure in FIG. 16, the gate electrode in a unit cell is divided into two gates of the Gc gate 231 and the Gs gate 232, and these are driven separately. Moreover, by driving the Gc gate 231 and the Gs gate 232 with a time difference, it is possible to reduce turn-off loss and turn-on loss. Note that the timing for driving the Gc gate 231 and the Gs gate 232 with a time difference and others will be described separately with reference to FIG. 18.

The cross-sectional structure of the dual-gate IGBT 810 illustrated in FIG. 16, in particular, the cross-sectional structure of the Gc gate 231 and the Gs gate 232 is similar to the structure of the gate electrode 23 of the MOS controlled diode 2 illustrated in FIG. 10. However, in the MOS controlled diode 2, the bottom of the gate insulating film 32 surrounding the gate electrode 23 is covered with the p-layer 13 and is not in contact with the n⁻ layer 12. Therefore, even when the gate voltage (V_{GA}) is +15 V, stable blocking characteristics are obtained.

FIG. 17 is a diagram illustrating an example of a circuit symbol indicating the dual-gate IGBT 810 in FIG. 16.

This circuit symbol is newly created for the convenience of describing the embodiment. Note that the cross-sectional structure of the dual-gate IGBT 810 indicated by the circuit symbol in FIG. 17 is not limited to that in FIG. 16, and may have another cross-sectional structure.

### Seventh Embodiment

Next, the seventh embodiment will be described. In the seventh embodiment, control of the power conversion device 1100 will be described.

FIG. 18 illustrates an example of drive waveforms (or drive signals) representing a method of controlling the Gc 231 and the Gs gate 232 of the dual-gate IGBT 810 and a Gd gate (gate electrode 23) of the MOS controlled diode 82 in upper and lower arms of the power conversion device 1100 in FIG. 15.

These drive waveforms are generated by a control circuit such as a microcomputer (not illustrated) based on a PWM signal having a pulse width A generated by the control circuit, while taking into consideration dead time (DT) and the like. For reference, FIG. 18 also illustrates drive waveforms of a gate (G) in a conventional general IGBT.

As illustrated in FIG. 18, when turning off the dual-gate IGBT 810, the control circuit turns off the Gc gate drive signal prior to the Gs gate drive signal by a time td_off. For example, the Gc gate drive signal is switched from +15 V to 0 V (or −15 V). In this way, the charge accumulated in the dual-gate IGBT 810 can be reduced. Next, after the time td_off has elapsed, the control circuit turns off the Gs gate drive signal, whereby the current of the dual-gate IGBT 810 can be quickly cut off because the accumulated charge has been reduced, and thus the turn-off loss of the dual-gate IGBT 810 can be reduced.

On the other hand, when turning on the dual-gate IGBT 810, the control circuit turns on the Gs gate drive signal prior to the Gc gate drive signal by a time td_on. Namely, the Gs gate drive signal is switched from 0 V (or −15 V) to +15 V. In this way, the dual-gate IGBT 810 can be switched slowly by only the Gc gate, making it possible to adjust dv/dt to a small value. Namely, the voltage change at the time of turn-on can be made smaller. Next, the control circuit can improve the conductivity modulation of the dual-gate IGBT 810 and reduce the conduction loss (on-voltage) by turning on the Gc gate drive signal. However, driving by only the Gc gate results in slow switching and increased turn-on loss. In that case, the turn-on loss can be reduced by simultaneously driving the Gs gate and the Gc gate.

Here, the relationship between the Gc gate drive signal and the Gs gate drive signal of the dual-gate IGBT 810 and the Gd gate drive signal of the MOS controlled diode 82 is as follows. The transition period mentioned here is defined as the period during which the Gd gate drive signal is switched from 0 V (or −15 V) to +15V, maintained at +15 V, and then returned from +15 V to 0 V (or −15 V).

In FIG. 18, before the Gs gate drive signal of the dual-gate IGBT 810 of the own arm is turned on, the Gd gate drive signal of the MOS controlled diode 82 of the paired arm connected in series is set to +15 V. Then, the Gc and Gs gate drive signals of the dual-gate IGBT 810 connected in parallel to this MOS controlled diode 82 are turned off. In this way, it is possible to reproduce the pulse width A of the PWM signal. By this control method, it is possible to consistently generate the Gd gate drive signal, the Gs gate drive signal, and the Gc gate drive signal from the PWM signal similar to conventional ones. Even if the circuit of the upper arm and the circuit of the lower arm each have three circuits as in FIG. 15, it does not change the fact that the Gd gate drive signal, the Gs gate drive signal, and the Gc gate drive signal of each circuit can still be consistently generated from the PWM signal.

The above-described MOS controlled diode 82, like the conventional diode, can reduce the reverse recovery current and the reverse recovery loss by reducing the lifetime of minority carriers in the n⁻ layer 12. In addition, in the case of the configuration in which a first MOS controlled diode (an example of a first semiconductor device) having a longer lifetime and a reduced forward voltage and a second MOS controlled diode (an example of a second semiconductor device) having a shorter lifetime and a reduced reverse recovery current (reverse recovery loss) are connected in parallel, the MOS controlled diode 82 further has an effect of reducing conduction loss.

With this configuration, during the forward direction, the conduction loss can be reduced by causing the current flow mainly through the first MOS controlled diode while maintaining the gate electrodes 23 of the first MOS controlled diode and the second MOS controlled diode at 0 V (or −15 V). Also, during the reverse recovery, the gate electrode 23 of the first MOS controlled diode is set to +15 V immediately before the reverse recovery, the flow of the main current is transferred to the second MOS controlled diode, and further the second MOS controlled diode is set to +15 V. In this way, the charge accumulated in the second MOS controlled diode is reduced, whereby the reverse recovery loss can be reduced due to the short lifetime of the second MOS controlled diode. Such a configuration and effect can be obtained owing to the new effect of the MOS controlled diode 82 according to this embodiment, which can control the diode current with the gate electrode.

Therefore, with the above-described configuration in which the first MOS controlled diode and the second MOS controlled diode are connected in parallel, it is possible to realize a composite MOS controlled diode that simultaneously takes advantage of the low conduction loss of the first MOS controlled diode and the low reverse recovery loss of the second MOS controlled diode.

Further, it is also possible to integrate the MOS controlled diode 82 and the dual-gate IGBT 810 described above in one semiconductor chip. By integrating them into one semiconductor substrate, the overall mounting area of the MOS controlled diode 82 and the dual-gate IGBT 810 can be reduced, so that the power conversion device 1100 can be made smaller.

In particular, the MOS controlled diode 82 corresponding to the MOS controlled diodes 2, 3, and 4 illustrated in FIG. 9 to FIG. 11 and the dual-gate IGBT 810 illustrated in FIG. 16 all have the similar side gate structure. Therefore, when these are to be combined, the integration into one semiconductor chip is easy. Of course, even the conventional single-gate IGBT 81 can be integrated in the same semiconductor chip as the MOS controlled diode 82 according to this embodiment.

As illustrated in FIG. 2(b), some conventionally proposed MOS controlled diodes have a p channel MOSFET connected in series to a p layer of a pn diode. In this MOS controlled diode, during the forward direction, a negative gate voltage (for example, −15 V) lower than the threshold voltage is applied to the p channel MOSFET to turn on the p channel MOSFET, thereby causing a forward current to flow through the pn junction. On the other hand, during the reverse recovery, a gate voltage higher than the threshold voltage (for example, 0 V or +15 V) is applied in advance immediately before the reverse recovery to turn off the p channel MOSFET, whereby the excess charge accumulated in the pn diode during the forward direction is reduced before the reverse recovery.

However, in this MOS controlled diode, a negative gate voltage (for example, −15 V) is indispensable during the forward direction. In other words, it is necessary to newly prepare a negative gate power supply. In order to operate this MOS controlled diode, a power supply of −15 V is further required, and the number of power supplies becomes three in total. This results in increased costs and larger gate circuits. Further, since a p channel MOSFET is connected in series to a pn diode, the on-resistance of the p channel MOSFET is superimposed in addition to the forward voltage drop of the pn diode during the forward direction, resulting in increased conduction loss in the MOS controlled diode.

In contrast, in the MOS controlled diode 82 according to this embodiment, a pn diode and an n channel MOSFET are connected in parallel between the anode (A) and cathode (K) in the equivalent circuit. In this case, a negative gate voltage is not always necessary for the MOS controlled diode 82. In other words, in a power conversion device, a negative gate voltage is not always necessary for the gate power supply of the IGBT connected in parallel. Therefore, it can be driven by the two-value gate power supply of 0 V and +15 V similar to the IGBT 81 and the dual-gate IGBT 810. Namely, the number of voltages of the gate power supply can be reduced. Therefore, as compared with the case where a negative gate voltage is necessary, the advantages of easier control, the simple gate circuit, and smaller size can be additionally achieved.

Further, some conventionally proposed MOS controlled diodes use an n channel MOSFET similar to an IGBT. In this case, the gate power supply voltage only requires two values similar to those for an IGBT, that is, the gate voltage of 0 V during the forward direction and the gate voltage of +15 V during the reverse recovery. In addition, since this MOS controlled diode has an n channel MOSFET formed in parallel to the pn diode, the on-resistance of the n channel MOSFET is not superimposed on the forward voltage drop of the pn diode during the forward direction, making it easier to achieve a low forward voltage drop.

However, this MOS controlled diode uses an n⁺ layer having a high impurity concentration for the source (S) of the n channel MOSFET. Also, immediately before or during the reverse recovery, the gate voltage must be set to a value equal to or higher than the threshold voltage of the n channel MOSFET (for example, +15 V). Therefore, an n+ inversion layer is also formed at the Si interface of the MOS gate surface of the n channel MOSFET, and a parasitic npn transistor with a wide n+ layer is formed together with the high-concentration n+ layer of the source (S). This parasitic npn transistor is prone to operate at high voltages, large currents, and high temperatures, and causes a problem of reducing the reverse recovery safe operating area, which is the switching tolerance during the reverse recovery.

In contrast, in the MOS controlled diode 82 of this embodiment, the p⁻ layer 130 having a low impurity concentration is used for the source (S) of the n channel MOSFET. This results in a smaller forward voltage drop and a larger reverse recovery safe operating area.

Moreover, the dual-gate IGBT 810 and the MOS controlled diode 82 described above can be easily manufactured by a semiconductor manufacturing process using silicon. Further, for example, by the driving illustrated in FIG. 18, the power conversion device 1100 such as an inverter can be safely and highly efficiently operated with low loss. As a result, it is possible to improve the efficiency of power consumption in the power conversion device 1100 such as an inverter device without using high-cost SiC. This can promote widespread use of the power conversion device 1100, and can promote energy conservation and new energy sources toward a decarbonized society. Note that the same is true of the power conversion device 1000 using the IGBT 810 and the MOS controlled diode 82.

Note that the present invention is not limited to the above-described embodiments and examples, and further includes various modifications. For example, the embodiments and examples have been described in detail to make the present invention easily understood, and are not necessarily limited to those having all of the described configurations. In addition, a part of the configuration of one embodiment or example may be replaced with a configuration of another embodiment or example, and a configuration of another embodiment or example may be added to a configuration of one embodiment or example. Furthermore, a configuration of another embodiment or example may be added to a part of the configuration of each embodiment or example, and a part of the configuration of each embodiment or example may be eliminated or replaced with a configuration of another embodiment or example.

### REFERENCE SIGNS LIST

1, 2, 3, 4, 82 . . . MOS controlled diode, 11 . . . n⁺ layer, 12 . . . n⁻ layer, 13, 130 . . . p⁻ layer, 14 . . . p⁺ layer, 15, 151 . . . p layer, 21 . . . cathode electrode, 22, 220 . . . anode electrode, 23 . . . gate electrode, 31, 31 . . . insulating film, 32 . . . gate insulating film, 131 . . . n layer, 132 . . . n⁺ layer, 81 . . . IGBT, 231 . . . Gc gate, 232 . . . Gs gate, 810 . . . dual-gate IGBT, 1000, 1100 . . . power conversion device

1. A power conversion device configured to convert electric power using a semiconductor device, the power conversion device comprising:
the semiconductor device including:
a first semiconductor layer of a first conductivity type;
a second semiconductor layer of the first conductivity type provided on one surface side of the first semiconductor layer and having an impurity concentration lower than that of the first semiconductor layer;
a third semiconductor layer of a second conductivity type provided on the one surface side of the second semiconductor layer;
a fourth semiconductor layer of the second conductivity type provided in contact with the third semiconductor layer and having an impurity concentration higher than that of the third semiconductor layer;
a cathode electrode provided on the other surface side of the first semiconductor layer;
an anode electrode provided on the one surface side of the third semiconductor layer and having a protruding portion in contact with the fourth semiconductor layer; and
gate electrodes provided so as to interpose the protruding portion in a direction intersecting a direction in which the first semiconductor layer, the second semiconductor layer, and the third semiconductor layer are stacked and to be in contact with the third semiconductor layer via a gate insulating film; and
a voltage applying unit configured to apply a forward voltage between the anode electrode and the cathode electrode during a forward direction, to apply a reverse voltage between the anode electrode and the cathode electrode during a reverse recovery, and to control a potential of the gate electrode to a potential at which an inversion layer is formed in the third semiconductor layer with respect to a potential of the anode electrode before the reverse recovery.

2. The power conversion device according to claim 1, further comprising:
a DC/AC conversion circuit configured by connecting a plurality of insulated gate bipolar transistors that turn on and off a current in series between a pair of DC terminals; and
an AC terminal connected between the plurality of insulated gate bipolar transistors,
wherein the semiconductor device is connected in anti-parallel to each of the plurality of insulated gate bipolar transistors.

3. The power conversion device according to claim 2,
wherein the insulated gate bipolar transistor includes, as the gate electrodes, a first gate and a second gate that can be independently controlled to be turned on and off.

4. The power conversion device according to claim 1,
wherein the semiconductor device has a configuration in which a first semiconductor device having a longer lifetime and a reduced forward voltage and a second semiconductor device having a shorter lifetime and a reduced reverse recovery current are connected in parallel.

5. A method of controlling a power conversion device when operating the power conversion device configured to convert electric power using a semiconductor device,
for the semiconductor device including:
a first semiconductor layer of a first conductivity type;
a second semiconductor layer of the first conductivity type provided on one surface side of the first semiconductor layer and having an impurity concentration lower than that of the first semiconductor layer;
a third semiconductor layer of a second conductivity type provided on the one surface side of the second semiconductor layer;
a fourth semiconductor layer of the second conductivity type provided in contact with the third semiconductor layer and having an impurity concentration higher than that of the third semiconductor layer;
a cathode electrode provided on the other surface side of the first semiconductor layer;
an anode electrode provided on the one surface side of the third semiconductor layer and having a protruding portion in contact with the fourth semiconductor layer; and
gate electrodes provided so as to interpose the protruding portion in a direction intersecting a direction in which the first semiconductor layer, the second semiconductor layer, and the third semiconductor layer are stacked and to be in contact with the third semiconductor layer via a gate insulating film,
the method performing control of applying a forward voltage between the anode electrode and the cathode electrode during a forward direction, applying a reverse voltage between the anode electrode and the cathode electrode during a reverse recovery, and controlling a potential of the gate electrode to a potential at which an inversion layer is formed in the third semiconductor layer with respect to a potential of the anode electrode before the reverse recovery, thereby operating the power conversion device.

6. The method of controlling the power conversion device according to claim 5,
wherein the power conversion device further includes:
a DC/AC conversion circuit configured by connecting a plurality of insulated gate bipolar transistors that turn on and off a current in series between a pair of DC terminals; and
an AC terminal connected between the plurality of insulated gate bipolar transistors,
wherein the semiconductor device is connected in anti-parallel to each of the plurality of insulated gate bipolar transistors,
wherein each of the insulated gate bipolar transistors includes two gates of a first gate and a second gate as gate electrodes, and
wherein the first gate and the second gate are independently controlled to be turned on and off.

7. The method of controlling the power conversion device according to claim 6,
wherein a drive signal of the first gate is turned off prior to a drive signal of the second gate when turning off the insulated gate bipolar transistor, and the drive signal of the second gate is turned on prior to the drive signal of the first gate when turning on the insulated gate bipolar transistor.

8. The method of controlling the power conversion device according to claim 6,
wherein the first gate and the second gate are simultaneously driven when turning on and turning off the insulated gate bipolar transistor.

9. A semiconductor device comprising:
a first semiconductor layer of a first conductivity type;
a second semiconductor layer of the first conductivity type provided on one surface side of the first semiconductor layer and having an impurity concentration lower than that of the first semiconductor layer;
a third semiconductor layer of a second conductivity type provided on the one surface side of the second semiconductor layer;
a fourth semiconductor layer of the second conductivity type provided in contact with the third semiconductor layer and having an impurity concentration higher than that of the third semiconductor layer;
a cathode electrode provided on the other surface side of the first semiconductor layer;
an anode electrode provided on the one surface side of the third semiconductor layer and having a protruding portion in contact with the fourth semiconductor layer; and
gate electrodes provided so as to interpose the protruding portion in a direction intersecting a direction in which the first semiconductor layer, the second semiconductor layer, and the third semiconductor layer are stacked and to be in contact with the third semiconductor layer via a gate insulating film.

10. The semiconductor device according to claim 9, further comprising a fifth semiconductor layer of the second conductivity type interposing the protruding portion in the intersecting direction, provided in the third semiconductor layer, and having an impurity concentration higher than that of the third semiconductor layer and lower than that of the fourth semiconductor layer.

11. The semiconductor device according to claim 10,
wherein the fifth semiconductor layer is provided so as to span from the fourth semiconductor layer to the gate insulating film.

12. The semiconductor device according to claim 10, further comprising a sixth semiconductor layer of the first conductivity type located on the one surface side relative to the fifth semiconductor layer and having an impurity concentration higher than that of the fifth semiconductor layer.

13. The semiconductor device according to claim 10, further comprising a sixth semiconductor layer of the first conductivity type located on the one surface side relative to the fifth semiconductor layer and being in contact with the protruding portion of the anode electrode with lower resistance as compared with a case of Schottky junction.

14. The semiconductor device according to claim 10, further comprising a sixth semiconductor layer of the first conductivity type located on the one surface side relative to the fifth semiconductor layer and having an impurity concentration higher than that of the third semiconductor layer and lower than that of the fourth semiconductor layer.

15. The semiconductor device according to claim 14,
wherein the sixth semiconductor layer has an impurity concentration lower than that of the fifth semiconductor layer.

16. The semiconductor device according to claim 14,
wherein at least one of the third semiconductor layer and the sixth semiconductor layer and the protruding portion of the anode electrode form a Schottky junction.

17. The semiconductor device according to claim 9, further comprising a seventh semiconductor layer of the second conductivity type provided in the third semiconductor layer and on the other surface side of the gate electrode and having an impurity concentration higher than that of the third semiconductor layer.

18. The semiconductor device according to claim 9,
wherein the gate electrode becomes thicker in the intersecting direction as getting closer to the other surface side.

19. The semiconductor device according to claim 9,
wherein the fourth semiconductor layer is provided so as to fall within a distance at which the gate insulating film protrudes into the third semiconductor layer.

20. The semiconductor device according to claim 9,
wherein a distance of the third semiconductor layer in the intersecting direction between the two adjacent gate electrodes and gate insulating films interposing the protruding portion therebetween is smaller than a distance between the two adjacent gate electrodes and gate insulating films interposing no protruding portion therebetween.

21. The semiconductor device according to claim 9,
wherein the gate electrode and the third semiconductor layer function as a metal oxide semiconductor field effect transistor.

22. The semiconductor device according to claim 21,
wherein a pn diode made up of the first semiconductor layer, the second semiconductor layer, the third semiconductor layer, and the fourth semiconductor layer and the metal oxide semiconductor field effect transistor are connected in parallel between the anode electrode and the cathode electrode when the semiconductor device is made into an equivalent circuit.

23. A semiconductor device comprising:
a first semiconductor layer of a first conductivity type;
a second semiconductor layer of the first conductivity type provided on one surface side of the first semiconductor layer and having an impurity concentration lower than that of the first semiconductor layer;
a third semiconductor layer of a second conductivity type provided on the one surface side of the second semiconductor layer;
a fourth semiconductor layer of the second conductivity type provided in contact with the third semiconductor layer and having an impurity concentration higher than that of the third semiconductor layer;
a cathode electrode provided on the other surface side of the first semiconductor layer;
an anode electrode provided on the one surface side of the third semiconductor layer and being in contact with the fourth semiconductor layer; and
a gate electrode provided adjacent to the anode electrode and the fourth semiconductor layer.

24. The semiconductor device according to claim 23,
wherein the gate electrode and the third semiconductor layer function as a metal oxide semiconductor field effect transistor, and
wherein a pn diode made up of the first semiconductor layer, the second semiconductor layer, the third semiconductor layer, and the fourth semiconductor layer and the metal oxide semiconductor field effect transistor are connected in parallel between the anode electrode and the cathode electrode when an own device is made into an equivalent circuit.

25. A method of controlling a semiconductor device,
for the semiconductor device including:
a first semiconductor layer of a first conductivity type;
a second semiconductor layer of the first conductivity type provided on one surface side of the first semiconductor layer and having an impurity concentration lower than that of the first semiconductor layer;
a third semiconductor layer of a second conductivity type provided on the one surface side of the second semiconductor layer;
a fourth semiconductor layer of the second conductivity type provided in contact with the third semiconductor layer and having an impurity concentration higher than that of the third semiconductor layer;
a cathode electrode provided on the other surface side of the first semiconductor layer;
an anode electrode provided on the one surface side of the third semiconductor layer and having a protruding portion in contact with the fourth semiconductor layer; and
gate electrodes provided so as to interpose the protruding portion in a direction intersecting a direction in which the first semiconductor layer, the second semiconductor layer, and the third semiconductor layer are stacked and to be in contact with the third semiconductor layer via a gate insulating film,
the method performing control of applying a forward voltage between the anode electrode and the cathode electrode during a forward direction, applying a reverse voltage between the anode electrode and the cathode electrode during a reverse recovery, and controlling a potential of the gate electrode to a potential at which an inversion layer is formed in the third semiconductor layer with respect to a potential of the anode electrode before the reverse recovery.

26. The method of controlling the semiconductor device according to claim 25,
wherein the potential of the gate electrode is controlled to the potential at which the inversion layer is formed in the third semiconductor layer with respect to the potential of the anode electrode even during the reverse recovery.

27. The method of controlling the semiconductor device according to claim 25,
wherein, during at least one of the forward direction and reverse blocking after the reverse recovery, a potential difference between the gate electrode and the anode electrode is set to 0 V, or the potential of the gate electrode is controlled to be a potential opposite to the potential at which the inversion layer is formed in the third semiconductor layer with respect to the potential of the anode electrode.

28. The method of controlling the semiconductor device according to claim 27,
wherein, during at least one of the forward direction and the reverse blocking after the reverse recovery, a voltage capable of forming an accumulation layer in the third semiconductor layer is applied.
